(19) United States
(12) Patent Application Publication
(10) Pub. No.: US 2014/0288885 A1
(43) Pub. Date: Sep. 25, 2014

(54) SIGNAL PROCESSING DEVICE, PULSE WAVE MEASURING APPARATUS, AND SIGNAL PROCESSING METHOD

(71) Applicant: Seiko Epson Corporation, Tokyo (JP)

(72) Inventor: Masanori MORITA, Fussa-shi (JP)

(73) Assignee: Seiko Epson Corporation, Tokyo (JP)

(21) Appl. No.: 14/214,259

(22) Filed: Mar. 14, 2014

(30) Foreign Application Priority Data
Mar. 19, 2013 (JP) 2013-056629
Mar. 19, 2013 (JP) 2013-056630

(51) Int. Cl. G01R 35/02; G01R 29/26

(52) U.S. Cl. CPC G01R 35/02; G01R 29/26
USPC 702/191

(57) ABSTRACT

A signal processing device includes: a first acquisition unit that acquires a first signal indicating a pulse wave of a living body from a first measuring unit that measures the pulse wave; a second acquisition unit that acquires a second signal indicating the pulse wave of the living body from a second measuring unit that measures the pulse wave at different sensitivities from the first measuring unit; an estimation unit that estimates a ratio of sensitivity of the first measuring unit to sensitivity of the second measuring unit from a first spectrum of the first signal and a second spectrum of the second signal; and a subtraction unit that subtracts the second spectrum from the first spectrum so as to cancel noise included in the first spectrum and the second spectrum, using the ratio estimated by the estimation unit.

This application claims priority to Japanese Patent Application No. 2013-056629, filed Mar. 19, 2013 and Japanese Patent Application No. 2013-056630, filed Mar. 19, 2013, the entirety of which is hereby incorporated by reference.

### BACKGROUND

1. Technical Field

The present invention relates to an apparatus for measuring a pulse wave of a living body.

2. Related Art

A pulse wave measuring apparatus performing calculation processing in order to remove a noise component has been developed.

### SUMMARY

An advantage of some aspects of the invention is that it provides a technique of removing noise from a plurality of signals including a wave pulse.

According to an aspect of the invention, there is provided a signal processing device including: a first acquisition unit that acquires a first signal indicating a pulse wave of a living body from a first measuring unit that measures the pulse wave; a second acquisition unit that acquires a second signal indicating the pulse wave of the living body from a second measuring unit that measures the pulse wave at different sensitivities from the first measuring unit; an estimation unit that estimates a ratio of sensitivity of the first measuring unit to sensitivity of the second measuring unit from a first spectrum of the first signal and a second spectrum of the second signal; and a subtraction unit that subtracts the second spectrum from the first spectrum so as to cancel noise included in the first spectrum and the second spectrum, using the ratio estimated by the estimation unit.

In the signal processing device, the estimation unit may estimate a ratio of an integration value of the first spectrum in a predetermined frequency band to an integration value of the second spectrum in the frequency band, as the sensitivity ratio.

In the signal processing device, the frequency band may be a frequency band corresponding to the pulse wave.

In the signal processing device, the frequency band may be within the range between 0.5 Hz and 3.5 Hz.

In the signal processing device, the estimation unit may estimate a ratio of a spectral intensity of a predetermined frequency band in the first spectrum to a spectral intensity of the frequency band in the second spectrum, as the sensitivity ratio.

In the signal processing device, the estimation unit may estimate a ratio of a spectral intensity of a frequency band that shows a spectral intensity which is equal to or greater than a threshold value in any one of the first spectrum and the second spectrum, to a spectral intensity of the frequency band of the other spectrum, as the sensitivity ratio.

In the signal processing device, the estimation unit may estimate a ratio of a spectral intensity of a frequency band which shows a spectral intensity selected in order from strong to weak in any one of the first spectrum and the second spectrum, to a spectral intensity of the frequency band of the other spectrum, as the sensitivity ratio.

The signal processing device may further include: a storage unit that stores a standard value which becomes a standard as the ratio of the sensitivity of the first measuring unit to the sensitivity of the second measuring unit; and a determination unit that determines whether or not there is any noise exceeding a determined proportion in the first spectrum and the second spectrum based on the ratio estimated by the estimation unit and the standard value stored in the storage unit, in which the subtraction unit may not perform subtraction in a case where the determination unit determines that there is no noise exceeding the determined proportion in the first spectrum and the second spectrum.

The signal processing device may further include a division unit that performs clustering of sets of frequencies and spectral intensities obtained from the first spectrum of the first signal and the second spectrum of the second signal and divides the respective first spectrum and the second spectrum into a plurality of frequency bands based on a result of the clustering, in which the estimation unit may estimate the ratio of the sensitivity of the first measuring unit to the sensitivity of the second measuring unit per frequency band divided by the division unit with respect to the first spectrum and the second spectrum, the subtraction unit may subtract the second spectrum from the first spectrum per the frequency band so as to cancel the noise included in the first spectrum using the ratio estimated by the estimation unit, and the signal processing device may further include a synthesis unit that synthesizes the subtraction result per the frequency band obtained from the subtraction unit and obtains a plurality of spectra of the frequency bands.

In the signal processing device, the division unit may divide the first spectrum and the second spectrum into two frequency bands.

The signal processing device may further include: a storage unit that stores a standard value which becomes a standard as the ratio of the sensitivity of the first measuring unit to the sensitivity of the second measuring unit; and a determination unit that determines whether or not there is any noise exceeding a determined proportion in the first spectrum and the second spectrum based on the ratio estimated by the estimation unit and the standard value stored in the storage unit, in which the subtraction unit may not perform subtraction in a case where the determination unit determines that there is no noise exceeding the determined proportion in each of the spectra.

A pulse wave measuring apparatus according to another aspect of the invention includes: a first measuring unit that measures a pulse wave of a living body; a second measuring unit that measures the pulse wave of the living body at different sensitivities from the first measuring unit; a first acquisition unit that acquires a first signal indicating the pulse wave from the first measuring unit; a second acquisition unit that acquires a second signal indicating the pulse wave from the second measuring unit; an estimation unit that estimates a ratio of sensitivity of the first measuring unit to sensitivity of the second measuring unit from a first spectrum of the first signal and a second spectrum of the second signal; and a subtraction unit that subtracts the second spectrum from the first spectrum so as to cancel the noise included in the first spectrum and the second spectrum, using the ratio estimated by the estimation unit.

A signal processing method according to still another aspect of the invention includes: acquiring, by a first acquisition unit, a first signal indicating a pulse wave of a living body from a first measuring unit that measures the pulse wave; acquiring, by a second acquisition unit, a second signal indicating the pulse wave of the living body from a second measuring unit that measures the pulse wave at different sensitivities from the first measuring unit; estimating, by an estimation unit, a ratio of sensitivity of the first measuring unit to sensitivity of the second measuring unit from a first spectrum of the first signal and a second spectrum of the second signal; and subtracting, by a subtraction unit, the second spectrum from the first spectrum so as to cancel noise included in the first spectrum and the second spectrum, using the ratio estimated by the estimation unit.

### BRIEF DESCRIPTION OF THE DRAWINGS

The invention will be described with reference to the accompanying drawings, wherein like numbers reference like elements.

FIG. 1 shows an outer appearance of a pulse wave measuring apparatus.

FIG. 2 shows a configuration of a pulse wave measuring apparatus.

FIGS. 3A and 3B show a disposition of each configuration of a measuring unit.

FIG. 4 shows a functional configuration of a control unit.

FIG. 5 is a flow diagram that shows an operation of a pulse wave measuring apparatus.

FIGS. 6A and 6B show states where a noise component is removed by a pulse wave measuring apparatus.

FIG. 7 is a diagram that shows a functional configuration of a control unit.

FIG. 8 is a flow diagram that shows an operation of a pulse wave measuring apparatus.

FIGS. 9A to 9C are graphs for illustrating clustering.

### DESCRIPTION OF EXEMPLARY EMBODIMENTS

### 1. First Embodiment

### 1-1. Overall Configuration

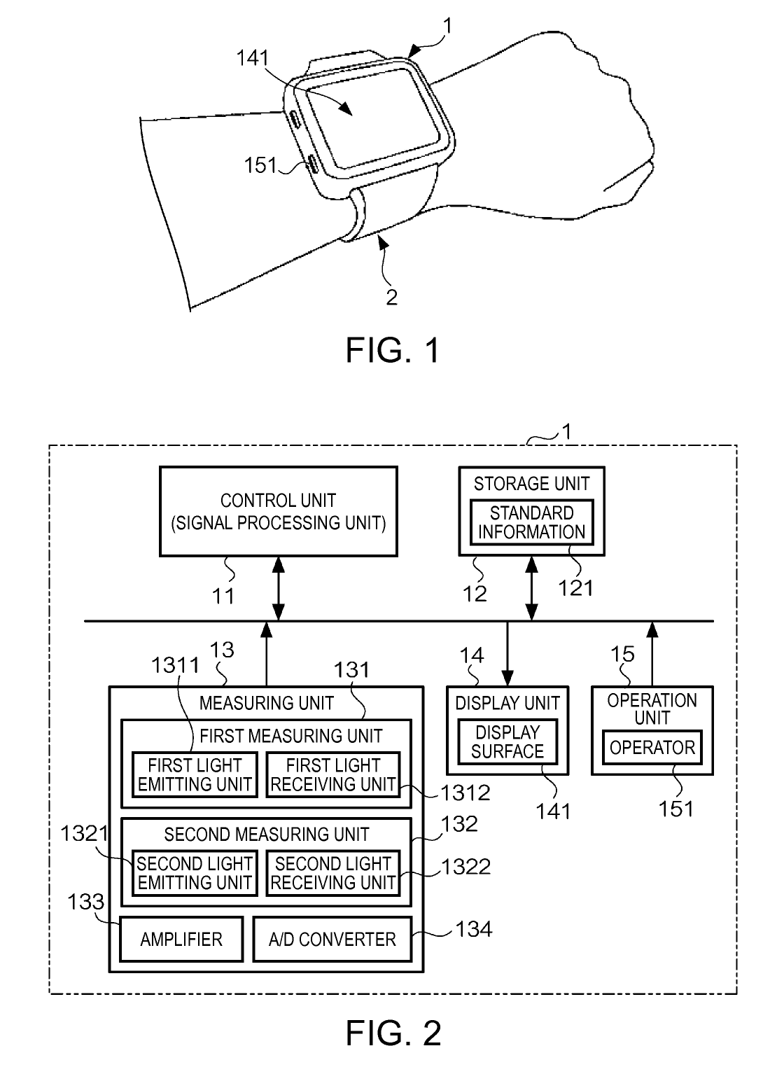

FIG. 1 shows an outer appearance of a pulse wave measuring apparatus 1. The pulse wave measuring apparatus 1 has a structure such as a wristwatch which is fixed to the wrist of a user using a wristband 2. A display surface 141 (to be described later) which is configured to have a liquid crystal panel or the like is installed on a surface of the pulse wave measuring apparatus 1 and an operator 151 (to be described later) such as a button switch operated by the user by pressing the button switch, is installed on a side surface of the pulse wave measuring apparatus 1. A back surface of the pulse wave measuring apparatus 1 comes in contact with the wrist of the user.

FIG. 2 is a block diagram that shows a configuration of the pulse wave measuring apparatus 1. A control unit 11 has Central Processing Unit (CPU), Read Only Memory (ROM), and Random Access Memory (RAM) and controls each unit of the pulse wave measuring apparatus 1 so that the CPU reads and executes a computer program (hereinafter, simply referred to as a program) stored in the ROM or in a storage unit 12.

The storage unit 12 is a storage device such as a solid state drive (SSD) and stores the program which is read by the CPU. In addition, the storage unit 12 stores standard information 121 as the information relating to a pulse wave which is measured in advance in a state where a proportion of noise is lower than a predetermined threshold value (hereinafter, referred to as a standard state). The standard information 121 is, for example, each integration value ratio or the like obtained by calculating respective power integration values with respect to two types of pulse wave signals which are measured in a standard state.

A display unit 14 is provided with the display surface 141 using a liquid crystal or the like and displays an image on the display surface 141 based on an instruction from the control unit 11.

An operation unit 15 is provided with the operator 151 such as the button switch for various instructions, receives the operation caused by the user, and supplies a signal based on the details of the operation to the control unit 11. The operator 151 may include a transparent touch panel which is superimposed on the display surface 141.

A measuring unit 13 has a first measuring unit 131, a second measuring unit 132, an amplifier 133, and an A/D converter 134. The first measuring unit 131 is configured to measure a pulse wave of a living body and to output a first signal indicating the pulse wave. Specifically, the first measuring unit 131 has a first light emitting unit 1311 and a first light receiving unit 1312 which are disposed so as to be in contact with the living body (in this case, a skin surface of the wrist).

The second measuring unit 132 is configured to measure the pulse wave of the living body at different sensitivities from the first measuring unit 131 and to output a second signal indicating the pulse wave. Here, “sensitivity” is the sensitivity of noise and represents a proportion of the noise component (intensity of a signal based on the noise) to the pulse wave component (intensity of a signal based on the pulse wave). Here, the sensitivity of the second measuring unit 132 is higher than the sensitivity of the first measuring unit 131.

Specifically, the second measuring unit 132 has a second light emitting unit 1321 and a second light receiving unit 1322 which are disposed so as to be in contact with the living body.

The amplifier 133 amplifies respective signals output from the first measuring unit 131 and the second measuring unit 132. The A/D converter 134 converts an analog signal amplified by the amplifier 133 into a digital signal.

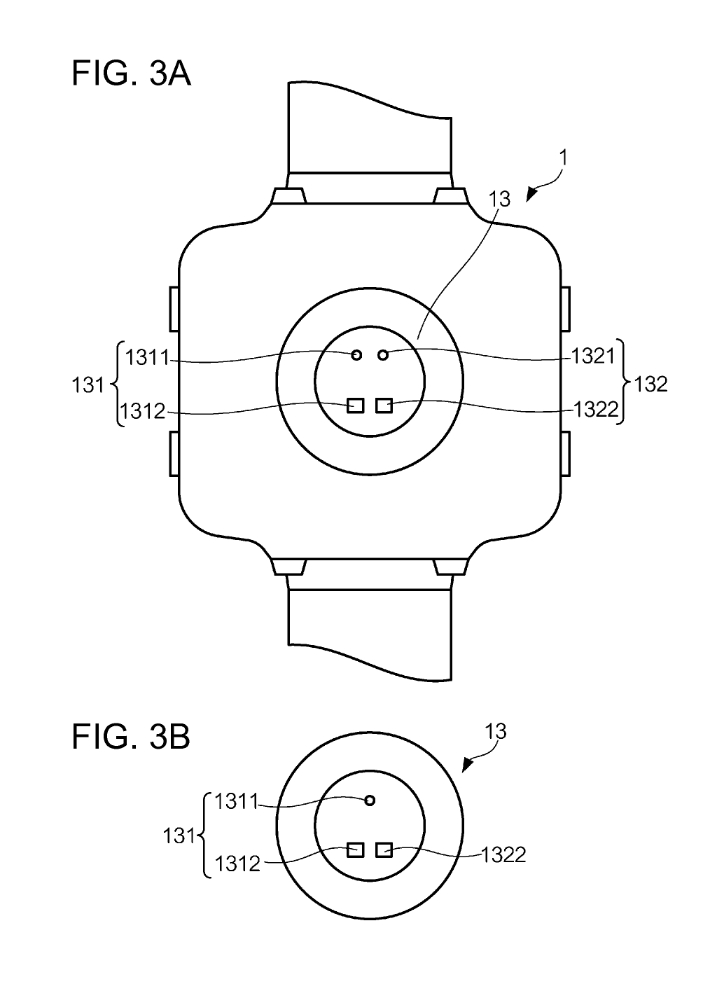

FIGS. 3A and 3B are diagrams that show disposition of each configuration of the measuring unit 13. As shown in FIG. 3A, all of the first light emitting unit 1311, the first light receiving unit 1312, the second light emitting unit 1321, and the second light receiving unit 1322 are disposed so as to be in contact with the skin surface of the wrist of the user in the pulse wave measuring apparatus 1. As shown in FIG. 3B, the first light emitting unit 1311 may serve as the second light emitting unit 1321 concurrently.

The first light emitting unit 1311 irradiates a biological tissue with light at a light amount corresponding to electric current which is supplied from a power source (not shown). Among lights with which the first light emitting unit 1311 irradiates the tissue, the first light receiving unit 1312 receives light which is reflected from the biological tissue and outputs the signal based on the intensity of the received light as a first signal. There may be various types of reflected light beams, and among them, the light which is reflected from hemoglobin in blood vessels indicates the pulse wave. Meanwhile, for example, if there is a movement of a body (body motion) of a user, then the reflected light becomes influenced by the movement and contains extraneous noise in the pulse wave in some cases.

The second light emitting unit 1321 irradiates the biological tissue with the light at the light amount corresponding to the electric current which is supplied from the power source. Among lights with which the second light emitting unit 1321 irradiates the tissue, the second light receiving unit 1322 receives the light which is reflected from the biological tissue and outputs the signal based on the intensity of the received light as a second signal. The second measuring unit 132 is configured to have the sensitivity different from the first measuring unit 131, as shown in the following (1) to (3), for example. Furthermore, these configurations may be combined with each other.

(1) The second light emitting unit 1321 and the second light receiving unit 1322 are disposed to have a distance from each other, the distance being different from a distance between the first light emitting unit 1311 and the first light receiving unit 1312.

(2) The second light emitting unit 1321 irradiates the tissue with the light having a different wavelength from the first light emitting unit 1311.

(3) The second light emitting unit 1321 or the second light receiving unit 1322 presses the living body at a pressure which is different from a pressure at which the first light emitting unit 1311 or the first light receiving unit 1312 presses the living body.

For example, the penetration depth of the light to the living body changes depending on the distance between the light emitting portion and the light receiving portion. The longer the distance is, the deeper the penetration depth is. In addition, in a case where there is a depth-dependent noise source in the living body, the first measuring unit 131 and the second measuring unit 132 measure respective pulse waves at different sensitivities from each other due to different distances between the light emitting unit and the light receiving unit.

In addition, an absorption coefficient of the hemoglobin in the blood vessels changes depending on the wavelength of the light with which the tissue is irradiated. In particular, because the absorption coefficient of oxygenated hemoglobin and the absorption coefficient of reduced hemoglobin are different from each other, a pulse wave signal which is strongly influenced by any one of arterial blood and venous blood is obtained by adjusting the wavelength so as to fit in any one of the absorption coefficients. In a case where the noise source is in any one of the artery and the vein, the first measuring unit 131 and the second measuring unit 132 respectively measure the pulse waves at different sensitivities from each other by making the wavelength of the irradiation light vary.

In addition, a degree to which or an area in which the biological tissue is crushed changes depending on the change of the pressure to a mounting surface. In particular, a dermic layer is crushed at a lower pressure due to a soft tissue which has a lot of capillaries. Accordingly, in a case where there is a noise source in the capillaries of the dermic layer, the first measuring unit 131 and the second measuring unit 132 respectively measure the pulse waves at different sensitivities from each other, depending on the contraction coefficient of the dermic layer.

### 1-2. Functional Configuration of Control Unit

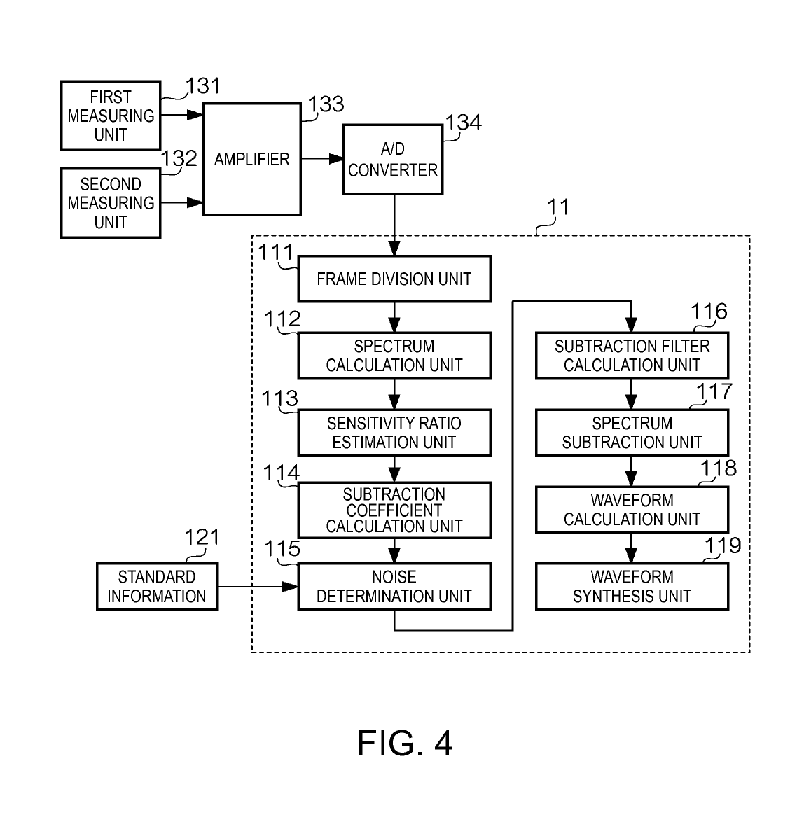

FIG. 4 is a diagram that shows a functional configuration of the control unit 11. The first signal output from the first measuring unit 131 and the second signal output from the second measuring unit 132 are respectively amplified through the amplifier 133 and are supplied to the control unit 11 after being converted into the digital signal using the A/D converter 134. That is, the control unit 11 functions as a first acquisition unit that acquires the first signal indicating the pulse wave from the first measuring unit 131 that measures the pulse wave of the living body. In addition, the control unit 11 functions as a second acquisition unit that acquires the second signal indicating the pulse wave from the second measuring unit 132 that measures the pulse wave of the living body at different sensitivities from the first measuring unit 131.

In addition, the control unit 11 functions as a frame division unit 111, a spectrum calculation unit 112, a sensitivity ratio estimation unit 113, a subtraction coefficient calculation unit 114, a noise determination unit 115, a subtraction filter calculation unit 116, a spectrum subtraction unit 117, a waveform calculation unit 118, and a waveform synthesis unit 119. Moreover, as the control unit 11 includes the aforementioned functions, it functions as the signal processing device that removes the noise included in the obtained first signal and second signal.

The frame division unit 111 divides the first signal and the second signal which are respectively output from the first measuring unit 131 and the second measuring unit 132 at predetermined intervals of times (hereinafter, referred to as “frame”). Here, the frame division unit 111 multiplies a window function to each divided frame so as to ease the analysis of the frequency components using the spectrum calculation unit 112 to be described later. For example, Hanning window function of ω(n) given by the following Formula (1) is used as the window function.

$$ω ( n ) = 0.5 - 0.5 cos ( \frac{2 π n}{N} ) \\ ( n = 0 , 1 , … , N ) \qquad ( 1 )$$

Here, N is the number of samples per frame and n represents a position of a sample within a frame.

The spectrum calculation unit 112 converts each signal which is divided by the frame division unit 111 into spectral information pieces by being processed using an algorithm such as Fast Fourier Transform. The intensity distribution of the frequency components included in each signal is obtained from the spectral information pieces.

The sensitivity ratio estimation unit 113 integrates each spectrum with respect to a predetermined frequency band (hereinafter, referred to as “target band”) using spectral information pieces respectively converted from the first signal and the second signal. Then, the sensitivity ratio estimation unit 113 estimates a noise sensitivity ratio NR based on each integration value obtained by the integration. The target band referred to herein is a component of a frequency band corresponding to the pulse (for example, 40 beats/min to 200 beats/min) which is expected by the pulse wave measuring apparatus 1, and is specifically in the range from 0.67 Hz to 3.33 Hz. Furthermore, the target band is preferably in the range from 0.5 Hz to 3.5 Hz.

The noise sensitivity ratio NR represents the ratio of the sensitivity of the second measuring unit 132 to the sensitivity of the first measuring unit 131. In this example, the noise sensitivity ratio NR is estimated. Although the noise sensitivity ratio NR is estimated using various methods, an estimation method using the integration value is used herein.

When the integration value of the target band included in the spectrum of the first signal (hereinafter, referred to as a first spectrum) is set as P₁, and the integration value of the target band included in the spectrum of the second signal (hereinafter, referred to as a second spectrum) is set as P₂, the noise sensitivity ratio NR is represented by the following Formula (2). That is, the sensitivity ratio estimation unit 113 estimates the noise sensitivity ratio NR based on Formula (2).

$$NR = \frac{{P}_{2}}{{P}_{1}} \qquad ( 2 )$$

That is, the sensitivity ratio estimation unit 113 functions as an estimation unit that estimates the ratio of the sensitivity of the second measuring unit 132 to the sensitivity of the first measuring unit 131 based on the first spectrum and the second spectrum.

The subtraction coefficient calculation unit 114 calculates a subtraction coefficient α using the noise sensitivity ratio NR which is estimated using the sensitivity ratio estimation unit 113. The subtract coefficient α is represented by the following Formula (3) as a reciprocal number of the noise sensitivity ratio NR. That is, the subtraction coefficient calculation unit 114 calculates the subtract coefficient α based on Formula (3).

$$α = \frac{1}{NR} = \frac{{P}_{1}}{{P}_{2}} \qquad ( 3 )$$

The noise determination unit 115 determines whether or not there is any noise exceeding a determined proportion in the first spectrum and the second spectrum. Specifically, the noise determination unit 115 determines whether or not there is any noise exceeding the above-described proportion by examining the subtract coefficient α which is calculated by the subtraction coefficient calculation unit 114, referring to the standard information 121 stored in the storage unit 12.

That is, the storage unit 12 storing the standard information 121 functions as a storage unit that stores a standard value which becomes a standard as the ratio of the sensitivity of the first measuring unit 131 to the sensitivity of the second measuring unit 132.

In addition, the noise determination unit 115 functions as a determination unit that determines whether there is any noise exceeding the determined proportion in the first spectrum and the second spectrum based on the ratio (noise sensitivity ratio NR) estimated by the estimation unit (sensitivity ratio estimation unit 113) and the standard value (standard information 121) stored in the storage unit 12.

There is provided an integration value of each spectrum of the first signal and the second signal which are previously measured in a standard state or a pulse wave coefficient β as a ratio of these integration values, in the standard information 121. For example, the noise determination unit 115 divides the subtract coefficient α which is calculated by the subtraction coefficient calculation unit 114 by the pulse wave coefficient β, and determines whether or not the obtained value (α/β) is higher than a predetermined lower limit value L and is lower than a predetermined upper limit value H. Then, if it is determined that the value (α/β) is higher than the lower limit value L and is lower than the upper limit value H, then the noise determination unit 115 determines that there is no noise exceeding the determined proportion in the first spectrum and the second spectrum.

The subtraction filter calculation unit 116 calculates a filter coefficient H(ω) of the spectrum subtraction using the subtract coefficient α, X₁(ω) as the first spectrum, and X₂(ω) as the second spectrum which are calculated by the subtraction coefficient calculation unit 114 based on the following Formula (4).

$$H ( ω ) = \{ \begin{matrix}1.0 & ( 1.0 < 1.0 - \frac{α \vert {X}_{2} ( ω ) \vert}{\vert {X}_{1} ( ω ) \vert} ) \\ 1 , 0 - \frac{α \vert {X}_{2} ( ω ) \vert}{\vert {X}_{1} ( ω ) \vert} & ( 0.0 \leq 1.0 - \frac{α \vert {X}_{2} ( ω ) \vert}{\vert {X}_{1} ( ω ) \vert} \leq 1.0 ) \\ 0.0 & ( 1.0 - \frac{α \vert {X}_{2} ( ω ) \vert}{\vert {X}_{1} ( ω ) \vert} < 0.0 )\end{matrix} \qquad ( 4 )$$

The spectrum subtraction unit 117 subtracts each spectrum by applying the filter coefficient calculated by the subtraction filter calculation unit 116 to the first spectrum and the second spectrum. Specifically, in the process of subtracting X₂(ω), which is multiplied by the subtract coefficient α, from X₁(ω), if the spectrum after the subtraction is set as S(ω), S(ω) is represented by the following Formula (5).

$$\begin{matrix}S ( ω ) = ( \vert {X}_{1} ( ω ) \vert - α \vert {X}_{2} ( ω ) \vert ) {e}^{j∠ {X}_{1} ( ω )} \\ = \vert {X}_{1} ( ω ) \vert {e}^{j∠ {X}_{1} ( ω )} - α \vert {X}_{2} ( ω ) \vert {e}^{j∠ {X}_{1} ( ω )} \\ = ( 1.0 - \frac{α \vert {X}_{2} ( ω ) \vert}{\vert {X}_{1} ( ω ) \vert} ) \vert {X}_{1} ( ω ) \vert {e}^{j∠ {X}_{1} ( ω )} \\ = ( 1.0 - \frac{α \vert {X}_{2} ( ω ) \vert}{\vert {X}_{1} ( ω ) \vert} ) FFT [ x ( t ) ] \\ = H ( ω ) {X}_{1} ( ω )\end{matrix} \qquad ( 5 )$$

Here, x(t) is the first signal which is measured in the first measuring unit 131. That is, the subtraction process is the same as the process of filtering the first signal using the filter coefficient H(ω). The spectrum S(ω) where the noise included in each spectrum is canceled is obtained as a result of the subtraction process. That is, the subtraction coefficient calculation unit 114, the subtraction filter calculation unit 116 and the spectrum subtraction unit 117 function as subtraction units that subtract one from another among the spectra so as to cancel the noise which is included in each spectrum, using the ratio (noise sensitivity ratio NR) estimated by the estimation unit (sensitivity ratio estimation unit 113). In this case, the subtraction coefficient calculation unit 114, the subtraction filter calculation unit 116, and the spectrum subtraction unit 117 cancel the noise which is included in each spectrum by subtracting the second spectrum from the first spectrum. In addition, the meaning of the “subtracting of a spectrum so as to cancel the noise” referred to herein is not limited to a case where the noise which is included in each spectrum is completely removed, and also includes a case where the noise which is included in each spectrum is decreased compared to the state before subtraction.

However, in a case where the noise determination unit 115 determines that there is no noise exceeding the determined proportion in the spectra, the spectrum subtraction unit 117 does not perform the above-described subtraction process and outputs any one of the spectra as it is. Furthermore, the output spectrum may be predetermined, and, for example, a spectrum relatively having a low sensitivity may be selected.

The waveform calculation unit 118 calculates a waveform in a time domain by performing inverse Fourier transform of the output of the spectrum subtraction unit 117.

The waveform synthesis unit 119 synthesizes the waveform calculated by the waveform calculation unit 118 to output the waveform.

### 1-3. Operation

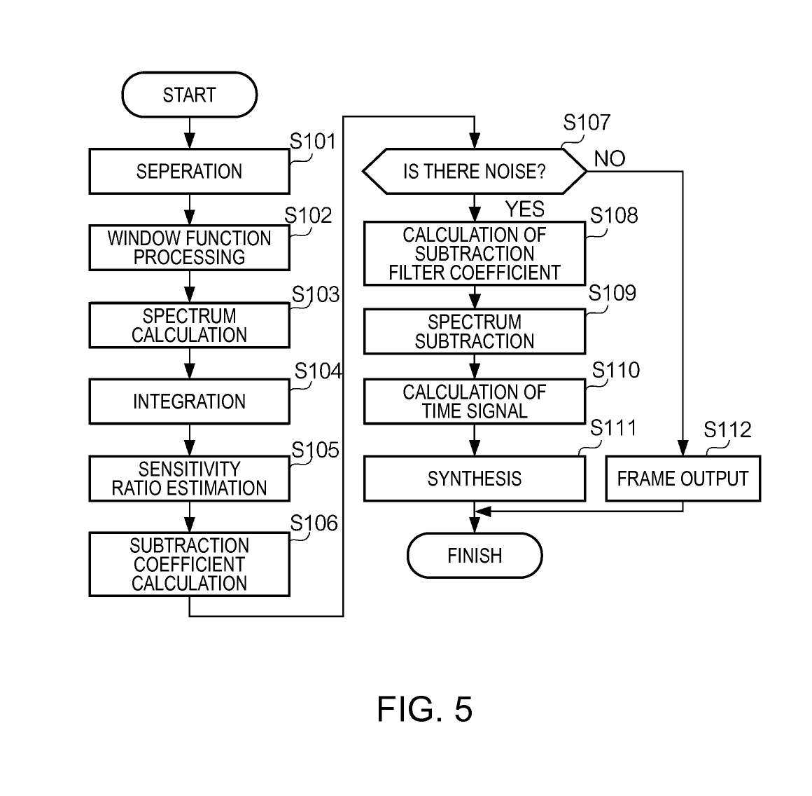

FIG. 5 is a flow diagram that shows an operation of the pulse wave measuring apparatus 1. When the control unit 11 of the pulse wave measuring apparatus 1 receives the first signal and the second signal from the measuring unit 13, the control unit 11 divides each signal into frames (Step S101). The control unit 11 performs a process of multiplying the window function to the divided signals (window function process) (Step S102). Moreover, the control unit 11 calculates the spectrum by performing the Fast Fourier Transform or the like with respect to the signal which is subjected to the window function process (Step S103). The control unit 11 integrates the respective target bands of the spectra (Step S104) and estimates the noise sensitivity ratio NR from the obtained integration value (Step S105). In addition, the control unit 11 calculates the subtract coefficient α based on the estimated noise sensitivity ratio NR (Step S106).

Next, the control unit 11 determines whether or not there is any noise exceeding the determined proportion in the first spectrum and the second spectrum based on the pulse wave coefficient β which is read from the standard information 121 and the subtract coefficient α which is calculated in Step S106 (Step S107). When it is determined that there is noise (Step S107; Yes), the control unit 11 calculates the filter coefficient of the spectrum subtraction using the calculated subtract coefficient α (Step S108). Further, the control unit 11 performs the subtraction of each spectrum by applying the calculated filter coefficient (Step S109). Then, the control unit 11 calculates a time signal by performing the inverse Fourier Transform using the subtracted spectrum (Step S110). The control unit 11 further calculates a synthesized waveform which is obtained by overlap-adding the time signal (Step S111). Meanwhile, when it is determined that there is no noise (Step S107; No), the control unit 11 outputs the frames separated in Step S101 as they are (Step S112).

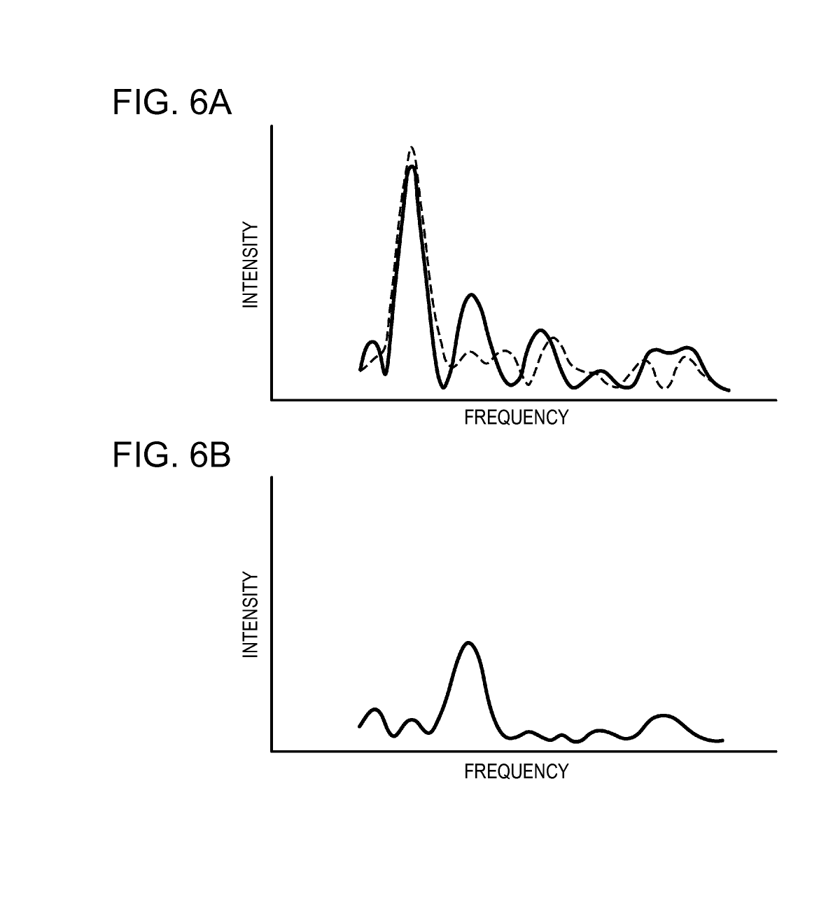

FIGS. 6A and 6B are graphs showing examples in which the noise component is removed by the pulse wave measuring apparatus 1. In FIG. 6A, the solid line shows the first spectrum obtained by converting the first signal which is output by the first measuring unit 131 and the dashed line shows the second spectrum obtained by converting the second signal which is output by the second measuring unit 132. When the pulse wave measuring apparatus 1 calculates the ratio of the sensitivity of the second measuring unit 132 to the sensitivity of the first measuring unit 131 and performs the subtraction process using the ratio, a spectrum shown in FIG. 6B is obtained. The spectrum is a signal in which the noise included in each of the first signal and the second signal is removed and the target band is extracted.

As described above, since the pulse wave measuring apparatus 1 removes the noise included in the signal which is output by each measuring unit using the difference between the two measuring units in sensitivity, it is possible to measure the pulse wave with high accuracy compared to the related art.

### 1-4. Modification Examples

Although First Embodiment of the invention has been described above, the content of First Embodiment can be modified as follows. In addition, the following Modification Examples may be combined with each other.

### 1-4-1. Modification Example 1

In the above-described First Embodiment, the sensitivity ratio estimation unit 113 estimates the ratio of the integration value of the first spectrum to the integration value of the second spectrum as the noise sensitivity ratio NR, but the method of estimating the noise sensitivity ratio NR is not limited thereto. The sensitivity ratio estimation unit 113 may estimate a ratio of a spectral intensity of a frequency band that shows a spectral intensity which is equal to or greater than a threshold value in any one of the first spectrum and the second spectrum, to a spectral intensity of the frequency band of the other spectrum, as the sensitivity ratio.

For example, the sensitivity ratio estimation unit 113 specifies the frequency band that shows the spectral intensity which is equal to or greater than the determined threshold value from the first spectrum (hereinafter, referred to as a first spectral intensity) and specifies the spectral intensity of the frequency band in the second spectrum (hereinafter, referred to as a second spectral intensity). Then, the sensitivity ratio estimation unit 113 may estimate the ratio of the second spectral intensity to the first spectral intensity as the noise sensitivity ratio NR.

In a case where the noise is more strongly measured than the pulse wave continuously, there is a high possibility that the spectrum is noise, and not the pulse wave, as the spectral intensity is strong. It is possible to estimate the noise sensitivity ratio NR with high accuracy even in a case where it is unclear as to at which frequency band the real noise occurs, by the sensitivity ratio estimation unit 113 that specifies the frequency band which shows the spectral intensity equal to or greater than the threshold value in any one of the spectra and specifies the spectral intensity of the frequency band in the other to calculate the ratio of these spectral intensities, as described above.

Furthermore, in a case where there are a plurality of first spectral intensities that show values equal to or greater than the determined threshold value, the noise sensitivity ratio NR may be estimated based on a plurality of ratios which are obtained by specifying the second spectral intensities corresponding to the first spectral intensities and by calculating the ratios with respect to each of the sets of the intensities. For example, an additive average value of the plurality of ratios may be set as the noise sensitivity ratio NR.

### 1-4-2. Modification Example 2

In addition, the sensitivity ratio estimation unit 113 may estimate the ratio of the spectral intensity of the frequency band that shows the spectral intensity which is selected in order from strong to weak in any one of the first spectrum and the second spectrum, to the spectral intensity of the frequency band of the other spectrum, as the sensitivity ratio.

For example, the sensitivity ratio estimation unit 113 selects the plurality of first spectral intensities which are determined in order from strong to weak from the first spectrum and specifies the frequency band that shows the first spectral intensities. Moreover, the sensitivity ratio estimation unit 113 specifies the spectral intensity of the frequency band in the second spectrum as the second spectral intensity. Moreover, the sensitivity ratio estimation unit 113 may estimate the ratio of the second spectral intensity to the first spectral intensity as the noise sensitivity ratio NR. It is possible to estimate the noise sensitivity ratio NR at high accuracy according to this configuration as well.

### 1-4-3. Modification Example 3

In addition, the sensitivity ratio estimation unit 113 may also estimate the ratio of the spectral intensity of a predetermined frequency band in the first spectrum to the spectral intensity of the frequency band in the second spectrum as a sensitivity ratio. For example, the sensitivity ratio estimation unit 113 specifies each of spectral intensities in a band (predetermined frequency band) deviated from the above-described target band, as in the range between 3.6 Hz and 4.0 Hz in the first spectrum and the second spectrum. Moreover, the sensitivity ratio estimation unit 113 may estimate the ratio of the specified spectral intensities as the noise sensitivity ratio NR.

According to this configuration, it is possible to estimate the noise sensitivity ratio NR at high accuracy in a case where it is previously known in which frequency band the noise occurs.

### 1-4-4. Modification Example 4

In the First Embodiment described above, the noise determination unit 115 determines whether or not there is any noise exceeding the determined proportion in the first spectrum and the second spectrum by examining the subtract coefficient α which is calculated by the subtraction coefficient calculation unit 114, referring to the standard information 121. However, the control unit 11 may not function as the noise determination unit 115. In this case, the storage unit 12 may not store the standard information 121. Moreover, in this case, the subtraction filter calculation unit 116 may calculate the filter coefficient of the spectrum subtraction whatever value the subtraction coefficient α calculated by the subtraction coefficient calculation unit 114 has, and the spectrum subtraction unit 117 may perform subtraction of each spectrum by applying the filter coefficient to the first spectrum and the second spectrum.

### 2. Second Embodiment

### 2-1. Overall Configuration

As an overall configuration of Second Embodiment is common to First Embodiment, description thereof will be omitted.

### 2-2. Functional Configuration of Control Unit

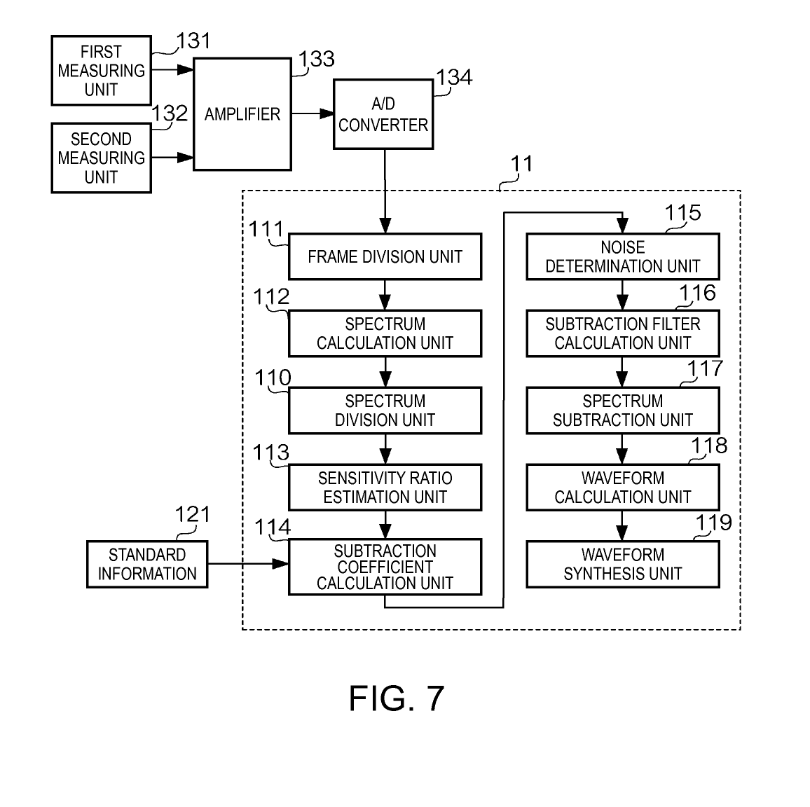

FIG. 7 is a diagram that shows a functional configuration of a control unit 11. A first signal output from a first measuring unit 131 and a second signal output from a second measuring unit 132 are respectively amplified through an amplifier 133 and are supplied to the control unit 11 after being converted into a digital signal using an A/D converter 134. That is, the control unit 11 functions as a first acquisition unit that acquires the first signal indicating a pulse wave from the first measuring unit 131 that measures the pulse wave of the living body. In addition, the control unit 11 functions as a second acquisition unit that acquires the second signal indicating the pulse wave from the second measuring unit 132 that measures the pulse wave of the living body at different sensitivities from the first measuring unit 131.

In addition, the control unit 11 functions as a frame division unit 111, a spectrum calculation unit 112, a spectrum division unit 110, a sensitivity ratio estimation unit 113, a subtraction coefficient calculation unit 114, a noise determination unit 115, a subtraction filter calculation unit 116, a spectrum subtraction unit 117, a spectrum synthesis unit 118, a waveform calculation unit 1191, and a waveform synthesis unit 1192. Moreover, as the control unit 11 includes the aforementioned functions, it functions as a signal processing device that removes noise included in the obtained first signal and second signal.

The frame division unit 111 divides the first signal and the second signal which are respectively output from the first measuring unit 131 and the second measuring unit 132 per frame. Here, the frame division unit 111 multiplies a window function to each divided frame so as to ease the analysis of the frequency components using the spectrum calculation unit 112 to be described later. For example, Hanning window function ω(n) given by Formula (1) described above is used as the window function.

The spectrum calculation unit 112 converts each signal which is divided by the frame division unit 111 into spectral information pieces by being processed using an algorithm such as Fast Fourier Transform. Intensity distribution of the frequency components included in each signal, that is, frequency spectrum is obtained from the spectral information pieces.

The spectrum division unit 110 divides the spectral information pieces converted from the first signal and the second signal by the spectrum calculation unit 112 into a plurality of clusters. The clusters referred to herein are a subset of a universal set and a component group in which the components having common characteristics among components consisting the universal set are grouped together. The division of the spectral information pieces into the plurality of clusters is referred to as clustering. Hereinafter, the spectral information pieces divided into the plurality of clusters are referred to as divided spectral information pieces. Specifically, the spectrum division unit 110 performs the clustering on sets of the frequencies and the spectral intensities which are obtained from the spectrum of the first signal (hereinafter, referred to as a first spectrum) and the spectrum of the second signal (hereinafter, referred to as a second spectrum), and based on the result, the spectrum division unit 110 divides the first spectrum and the second spectrum into a plurality of frequency bands.

The sensitivity ratio estimation unit 113 estimates the ratio of the sensitivity of the first measuring unit to the sensitivity of the second measuring unit per frequency band divided by the spectrum division unit 110 with respect to the first spectrum and the second spectrum. Specifically, the sensitivity ratio estimation unit 113 integrates each spectrum of the first signal and the second signal per frequency band (hereinafter, referred to as a partial band) where the divided spectral information pieces are shown, using the divided spectral information pieces which are divided into plural pieces by the spectrum division unit 110. Moreover, the sensitivity ratio estimation unit 113 estimates the noise sensitivity ratio NR per partial band based on each integration value obtained by the integration.

The noise sensitivity ratio NR is a value obtained by estimating the ratio of the sensitivity of the second measuring unit 132 to the sensitivity of the first measuring unit 131. Although the noise sensitivity ratio NR can be estimated using various methods, an estimation method using the integration value is used herein.

When the integration value of the partial band included in the first spectrum is set as P₁, and the integration value of the partial band included in the second spectrum is set as P₂, the noise sensitivity ratio NR in the partial band is represented by the above-described Formula (2). That is, the sensitivity ratio estimation unit 113 estimates the noise sensitivity ratio NR based on Formula (2).

That is, the sensitivity ratio estimation unit 113 functions as an estimation unit that estimates the ratio of the sensitivity of the second measuring unit 132 to the sensitivity of the first measuring unit 131 based on the first spectrum and the second spectrum.

The subtraction coefficient calculation unit 114 calculates a subtraction coefficient α using the noise sensitivity ratio NR which is estimated using the sensitivity ratio estimation unit 113. The subtract coefficient α is represented by the above-described Formula (3) as a reciprocal number of the noise sensitivity ratio NR. That is, the subtraction coefficient calculation unit 114 calculates the subtract coefficient α based on Formula (3).

The noise determination unit 115 determines whether or not there is any noise exceeding a determined proportion in the first spectrum and the second spectrum per partial band. Specifically, the noise determination unit 115 determines whether or not there is any noise exceeding the above-described proportion by examining the subtract coefficient α which is calculated by the subtraction coefficient calculation unit 114, referring to the standard information 121 stored in the storage unit 12.

That is, the storage unit 12 storing the standard information 121 functions as a storage unit that stores a standard value which becomes a standard as the ratio of the sensitivity of the first measuring unit 131 to the sensitivity of the second measuring unit 132.

In addition, the noise determination unit 115 functions as a determination unit that determines whether or not there is any noise exceeding the determined proportion in the first spectrum and the second spectrum based on the ratio (noise sensitivity ratio NR) estimated by the estimation unit (sensitivity ratio estimation unit 113) and the standard value (standard information 121) stored in the storage unit 12.

There is provided an integration value of each spectrum of the first signal and the second signal which are previously measured in a standard state or a pulse wave coefficient β as a ratio of these integration values, in the standard information 121. For example, the noise determination unit 115 divides the subtract coefficient α which is calculated by the subtraction coefficient calculation unit 114 by the pulse wave coefficient β, and determines whether or not the obtained value (α/β) is higher than a predetermined lower limit value and is lower than a predetermined upper limit value. Then, when it is determined that the value (α/β) is higher than the lower limit value and is lower than the upper limit value, the noise determination unit 115 determines that there is no noise exceeding the determined proportion in the first spectrum and the second spectrum.

The subtraction filter calculation unit 116 calculates a filter coefficient H(ω) of the spectrum subtraction using the subtract coefficient α, X₁(ω) as the first spectrum, and X₂(ω) as the second spectrum which are calculated by the subtraction coefficient calculation unit 114 based on the above-described Formula (4).

The spectrum subtraction unit 117 subtracts each spectrum by applying the filter coefficient calculated by the subtraction filter calculation unit 116 to the first spectrum and the second spectrum. Specifically, in the process of subtracting X₂(ω), which is multiplied by the subtract coefficient α, from X₁(ω), if the spectrum after the subtraction is set as S(ω), S(ω) is represented by the above-described Formula (5).

In Formula (5), x(t) is the first signal which is measured in the first measuring unit 131. That is, the subtraction process is the same as the process of filtering the first signal by the filter coefficient H(ω). The spectrum S(ω) where the noise included in each spectrum is canceled is obtained as a result of the subtraction process. That is, the subtraction coefficient calculation unit 114, the subtraction filter calculation unit 116 and the spectrum subtraction unit 117 function as subtraction units that subtract one from another (here, the second spectrum from the first spectrum) among the spectra so as to cancel the noise which is included in the spectrum (here, the first spectrum) per partial band (frequency band), using the ratio (noise sensitivity ratio NR) estimated by the estimation unit (sensitivity ratio estimation unit 113). In addition, the meaning of the “subtracting of a spectrum so as to cancel the noise” referred to herein is not limited to a case where the noise which is included in each spectrum is completely removed, and also includes a case where the noise which is included in each spectrum is decreased compared to the state before subtraction.

However, in a case where the noise determination unit 115 determines that there is no noise exceeding the determined proportion in the spectra, the spectrum subtraction unit 117 does not perform the above-described subtraction process and outputs any one of the spectra as it is. Furthermore, the output spectrum may be predetermined, for example, a spectrum relatively having a low sensitivity may be selected.

The spectrum synthesis unit 118 synthesizes the subtraction result per partial band (frequency band) obtained by the spectrum subtraction unit 117 to obtain a plurality of spectra of the frequency bands.

The waveform calculation unit 1191 calculates the waveform in a time domain by performing inverse Fourier transform of the spectra obtained by the spectrum synthesis unit 118.

The waveform synthesis unit 1192 synthesizes the waveform calculated by the waveform calculation unit 1191 to output the waveform.

### 2-3. Operation

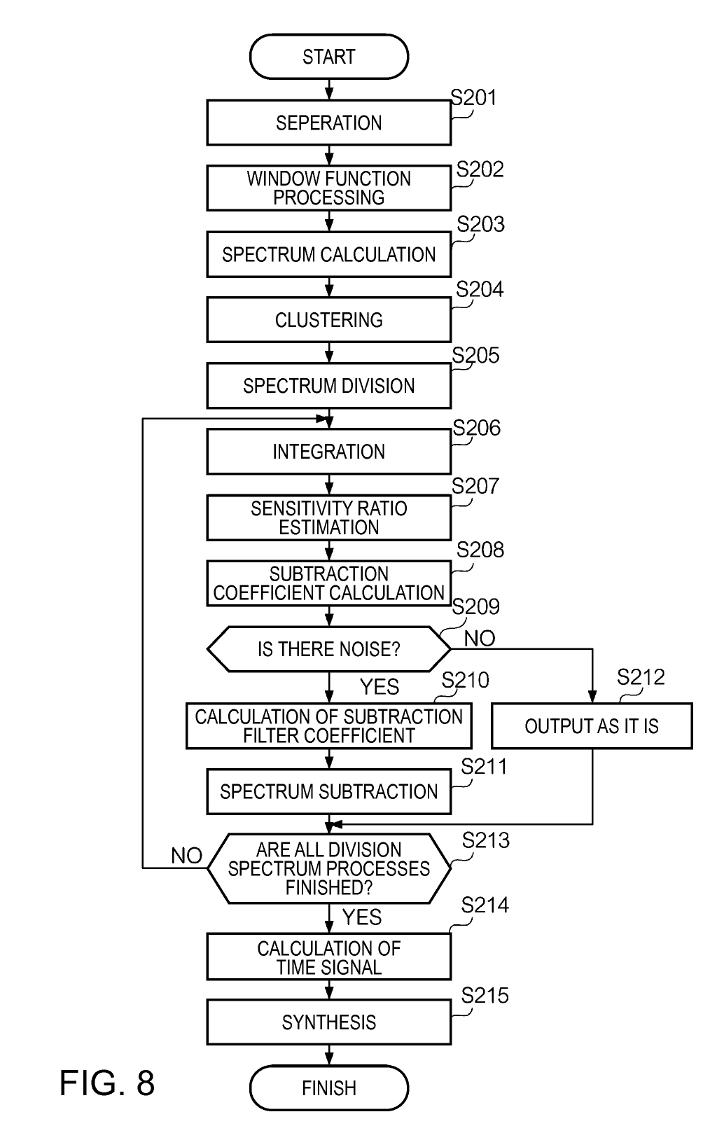

FIG. 8 is a flow diagram that shows an operation of the pulse wave measuring apparatus 1. When the control unit 11 of the pulse wave measuring apparatus 1 receives the first signal and the second signal from the measuring unit 13, the control unit 11 divides each signal into frames (Step S201). The control unit 11 performs a process of multiplying the window function to divided signals (window function process) (Step S202). Moreover, the control unit 11 calculates the spectrum by performing the Fast Fourier Transform or the like with respect to each frame which is subjected to the window function process (Step S203).

Next, the control unit 11 performs clustering of the first spectrum and the second spectrum (Step S204). The control unit 11 divides each spectrum per partial band (Step S205). Specifically, the control unit 11 plots points for which the intensity of the first spectrum and the intensity of the second spectrum are set as components on a plane coordinate per frequency, from the spectral information pieces obtained from the processes of up to Steps S203. Then, the control unit 11 divides the point groups into two clusters using k-means algorithm where a division number K is set as 2 on the plane coordinate.

For example, the control unit 11 allocates at random each point on the above-described plane coordinate to any one of the first cluster and the second cluster using a random number or the like. Then, the control unit 11 calculates the center of gravity of the point which is allocated to the first cluster and the center of gravity of the point which is allocated to the second cluster. Next, the control unit 11 calculates the distances between each of the calculated centers of gravity and each of the points, each of the points is newly allocated to a cluster that corresponds to a center of gravity having a shortest distance, and then the processes are repeated until when there is no change.

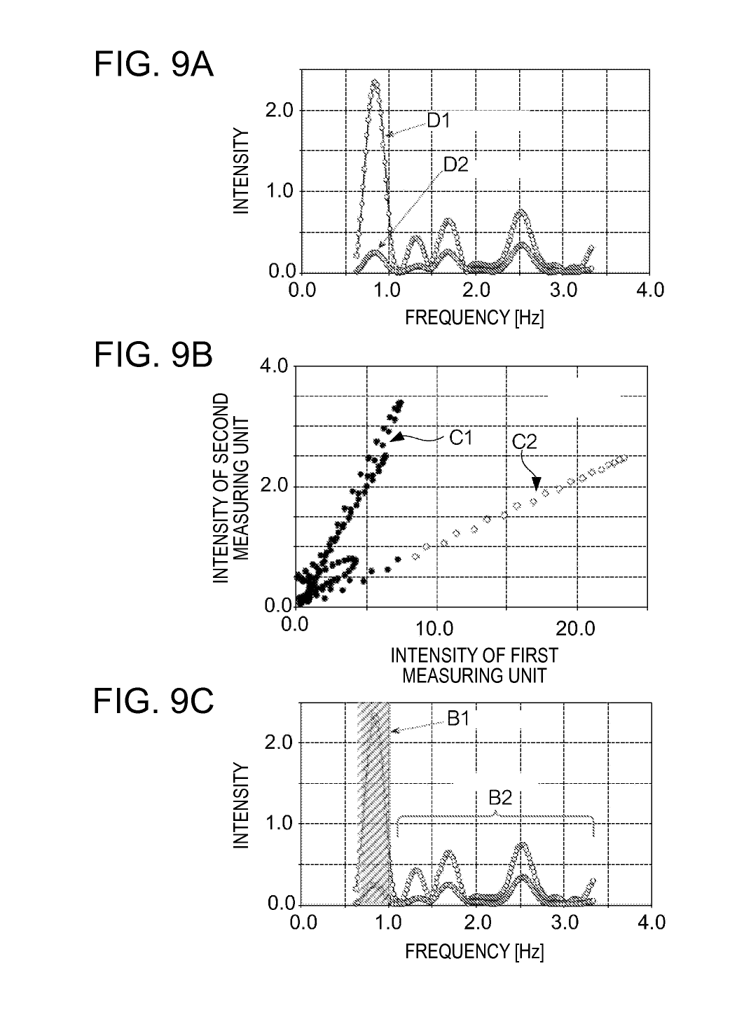

FIGS. 9A to 9C are graphs for illustrating the clustering. FIG. 9A shows an example of spectral information pieces obtained from the processes of up to Step S203. As shown in FIG. 9A, the first spectrum is represented by point group D1 and the second spectrum is represented by point group D2. FIG. 9B shows a scatter diagram in which these point groups are plotted on the plane coordinate for which the intensity of the first spectrum and the intensity of the second spectrum are set as the components. Each point on the scatter diagram is classified in any of a first cluster C1 and a second cluster C2 by performing the clustering based on k-means method with respect to the scatter diagram shown in FIG. 9B.

FIG. 9C is a graph to which the result of classifying the points in any of the first cluster C1 and the second cluster C2 is reflected in the spectral information of FIG. 9A. The result of the classification due to the clustering process is shown as the classification of the frequency band in the spectral information. That is, as shown in FIG. 9C, portions of the spectra corresponding to the points which belong to the first cluster C1 and the second cluster C2 are respectively represented as spectra of partial band B1 and partial band B2.

The control unit 11 performs the processes starting from the following Step S206 to Step S213 (hereinafter, referred to as division spectrum processes) per divided partial band after each spectrum is divided per partial band. The control unit 11 integrates the first spectrum and the second spectrum per partial band (Step S206), and estimates the noise sensitivity ratio NR from the obtained integration value per partial band (Step S207). In addition, the control unit 11 calculates the subtract coefficient α per partial band based on the estimated noise sensitivity ratio NR (Step S208).

Next, the control unit 11 determines whether or not there is any noise exceeding the determined proportion in the first spectrum and the second spectrum based on the pulse wave coefficient β which is read from the standard information 121 and the subtract coefficient α which is calculated in Step S208 (Step S209). When it is determined that there is noise (Step S209; Yes), the control unit 11 calculates the filter coefficient of the spectrum subtraction using the calculated subtract coefficient α (Step S210). Further, the control unit 11 performs the subtraction of each spectrum by applying the calculated filter coefficient (Step S211). Meanwhile, when it is determined that there is no noise (Step S209; No), the control unit 11 outputs any one of the spectra separated in Step S205 as it is (Step S212).

Then, when the division spectrum processes are finished in a certain partial band, the control unit 11 determines whether or not all the division spectrum processes are finished (Step S213). Then, if it is determined that all the division spectrum processes are not finished (Step S213; No), the control unit 11 performs the division spectrum processes with respect to the partial band for which the processes are not performed. Meanwhile, if it is determined that all the processes are finished (Step S213; Yes), the control unit 11 synthesizes the spectrum subtracted in Step S211 or the spectrum which is output in Step S212 as it is (Step S214). The control unit 11 further calculates a time signal, that is, the waveform by performing the inverse Fourier transform (Step S215). The control unit 11 further calculates a synthesized waveform which is obtained by overlap-adding the time signal (Step S216).

Examples in which the noise component is removed by the pulse wave measuring apparatus 1 are the same as those in FIGS. 6A and 6B. The solid line shown in FIG. 6A is the first spectrum obtained by converting the first signal which is output by the first measuring unit 131 and the dashed line shown in FIG. 6A is the second spectrum obtained by converting the second signal which is output by the second measuring unit 132. When the pulse wave measuring apparatus 1 divides each spectrum by performing the clustering, calculates the sensitivity ratios of the second measuring unit 132 to the first measuring unit 131 per divided division spectrum, determines whether or not there is noise using the ratios, and performs the subtraction processes depending on the determination result, a spectrum shown in FIG. 6B is obtained. The spectrum is a spectrum in which the noise included in the first spectrum or the second spectrum is removed.

As described above, since the pulse wave measuring apparatus 1 removes the noise included in the signal which is output by each measuring unit using the difference between the two measuring units in sensitivity, it is possible to measure the pulse wave with high accuracy compared to the related art. In addition, since the clustering is used, it is possible to specify the frequency band having different sensitivities of the two measuring units from each other.

### 2-4. Modification Examples

Although Second Embodiment of the invention has been described above, the content of Second Embodiment can be modified as the following. In addition, the following Modification Examples may be combined with each other.

### 2-4-1. Modification Example 1

In the above-described Second Embodiment, the sensitivity ratio estimation unit 113 estimates the ratio of the integration value of the first spectrum to the integration value of the second spectrum as the noise sensitivity ratio NR, but the method of estimating the noise sensitivity ratio NR is not limited thereto. The sensitivity ratio estimation unit 113 may estimate a ratio of a partial value showing an intensity which is equal to or greater than a threshold value in any one of the first spectrum and the second spectrum, to a partial value corresponding to the partial value which is equal to or greater than the threshold value in the other spectrum, as the sensitivity ratio.

For example, the sensitivity ratio estimation unit 113 specifies a peak value that shows the intensity which is equal to or greater than the determined threshold value from the first spectrum (hereinafter, referred to as a first peak value) and specifies a peak value in a band corresponding to the band that shows the first peak value in the second spectrum (hereinafter, referred to as a second peak value). Then, the sensitivity ratio estimation unit 113 may estimate the ratio of the second peak value to the first peak value as the noise sensitivity ratio NR.

In a case where the noise is more strongly measured than the pulse wave at all times, there is a high possibility that the spectrum is noise, not the pulse wave, as the spectral intensity is strong. It is possible to estimate the noise sensitivity ratio NR with high accuracy even in a case where it is unclear as to at which band the real noise occurs, by the sensitivity ratio estimation unit 113 that specifies a peak value which is equal to or greater than the threshold value in any one of the spectra and specifies a peak value corresponding to the peak value which is equal to or greater than the threshold value in the other spectrum to calculate the ratio of these peak values, as described above.

Furthermore, in a case where there are a plurality of first peak values that show values equal to or greater than the determined threshold value, the noise sensitivity ratio NR may be estimated based on a plurality of ratios which are obtained by specifying the second peak values corresponding to the first peak values and by calculating the ratios with respect to each of the sets of the values. For example, an additive average value of the plurality of ratios may be set as the noise sensitivity ratio NR.

### 2-4-2. Modification Example 2

In the above-described Second Embodiment, the point groups are divided by the control unit 11 into two clusters using k-means algorithm where a division number k is set as 2. However, the clustering algorithm is not limited to the k-means method. For example, other division optimization techniques such as K-medoids method may be used, or a hierarchical method such as nearest neighbor method may be used. The pulse wave measuring apparatus 1 can divide the point groups plotted on the above-described plane coordinate into a plurality of clusters even using a clustering algorithm other than the k-means method.

### 2-4-3. Modification Example 3

In addition, although the control unit 11 uses the k-means algorithm where the division number k is set as 2 in the above-described Second Embodiment, the division number K is not limited to 2, may be equal to or greater than 3. Having such a configuration, for example, since there are three noise sources or greater, even in a case where the noise sensitivity ratios of the second measuring unit to the first measuring unit are classified in three or greater, the pulse wave measuring apparatus 1 can subtract one from another among the spectra so as to cancel the noise which is included in each spectrum.

### 2-4-4. Modification Example 4

In the Second Embodiment described above, the noise determination unit 115 determines whether or not there is any noise exceeding the determined proportion in the first spectrum and the second spectrum by examining the subtract coefficient α which is calculated by the subtraction coefficient calculation unit 114, referring to the standard information 121. However, the control unit 111 may not function as the noise determination unit 115. In this case, the storage unit 12 may not store the standard information 121. Moreover, in this case, the subtraction filter calculation unit 116 may calculate the filter coefficient of the spectrum subtraction whatever value the subtraction coefficient α calculated by the subtraction coefficient calculation unit 114 has, and the spectrum subtraction unit 117 may perform subtraction of each spectrum by applying the filter coefficient to each of the spectra of the first signal and the second signal.

What is claimed is:

1. A signal processing device comprising:
a first acquisition unit that acquires a first signal indicating a pulse wave of a living body from a first measuring unit that measures the pulse wave;
a second acquisition unit that acquires a second signal indicating the pulse wave of the living body from a second measuring unit that measures the pulse wave at different sensitivities from the first measuring unit;
an estimation unit that estimates a ratio of sensitivity of the first measuring unit to sensitivity of the second measuring unit from a first spectrum of the first signal and a second spectrum of the second signal; and
a subtraction unit that subtracts the second spectrum from the first spectrum so as to cancel noise included in the first spectrum and the second spectrum, using the ratio estimated by the estimation unit.

2. The signal processing device according to claim 1, wherein the estimation unit estimates a ratio of an integration value of the first spectrum in a predetermined frequency band to an integration value of the second spectrum in the frequency band, as the sensitivity ratio.

3. The signal processing device according to claim 2, wherein the frequency band is a frequency band corresponding to the pulse wave.

4. The signal processing device according to claim 3, wherein the frequency band is within the range between 0.5 Hz and 3.5 Hz.

5. The signal processing device according to claim 1, wherein the estimation unit estimates a ratio of a spectral intensity of a predetermined frequency band in the first spectrum to a spectral intensity of the frequency band in the second spectrum, as the sensitivity ratio.

6. The signal processing device according to claim 5, wherein the estimation unit estimates a ratio of a spectral intensity of a frequency band that shows a spectral intensity which is equal to or greater than a threshold value in any one of the first spectrum and the second spectrum, to a spectral intensity of the frequency band of the other spectrum, as the sensitivity ratio.

7. The signal processing device according to claim 5, wherein the estimation unit estimates a ratio of a spectral intensity of a frequency band which shows a spectral intensity selected in order from strong to weak in any one of the first spectrum and the second spectrum, to a spectral intensity of the frequency band in the other spectrum, as the sensitivity ratio.

8. The signal processing device according to claim 1, further comprising:
a storage unit that stores a standard value which becomes a standard as the ratio of the sensitivity of the first measuring unit to the sensitivity of the second measuring unit; and
a determination unit that determines whether or not there is any noise exceeding a determined proportion in the first spectrum and the second spectrum based on the ratio estimated by the estimation unit and the standard value stored in the storage unit,
wherein the subtraction unit does not perform subtraction in a case where the determination unit determines that there is no noise exceeding the determined proportion in the first spectrum and the second spectrum.

9. The signal processing device according to claim 1, further comprising:
a division unit that performs clustering of sets of frequencies and spectral intensities obtained from the first spectrum of the first signal and the second spectrum of the second signal and divides the respective first spectrum and the second spectrum into a plurality of frequency bands based on a result of the clustering,
wherein the estimation unit estimates the ratio of the sensitivity of the first measuring unit to the sensitivity of the second measuring unit per frequency band divided by the division unit with respect to the first spectrum and the second spectrum,
wherein the subtraction unit subtracts the second spectrum from the first spectrum per the frequency band so as to cancel the noise included in the first spectrum using the ratio estimated by the estimation unit, and
wherein the signal processing device further comprises a synthesis unit that synthesizes the subtraction result per the frequency band obtained from the subtraction unit and obtains a plurality of spectra of the frequency bands.

10. The signal processing device according to claim 9, wherein the division unit divides the first spectrum and the second spectrum into two frequency bands respectively.

11. The signal processing device according to claim 9, further comprising:
a storage unit that stores a standard value which becomes a standard as the ratio of the sensitivity of the first measuring unit to the sensitivity of the second measuring unit; and
a determination unit that determines whether or not there is any noise exceeding a determined proportion in the first spectrum and the second spectrum based on the ratio estimated by the estimation unit and the standard value stored in the storage unit,
wherein the subtraction unit does not perform subtraction in a case where the determination unit determines that there is no noise exceeding the determined proportion in each of the spectra.

12. A pulse wave measuring apparatus comprising:
a first measuring unit that measures a pulse wave of a living body;
a second measuring unit that measures the pulse wave of the living body at different sensitivities from the first measuring unit;
a first acquisition unit that acquires a first signal indicating the pulse wave from the first measuring unit;
a second acquisition unit that acquires a second signal indicating the pulse wave from the second measuring unit;
an estimation unit that estimates a ratio of sensitivity of the first measuring unit to sensitivity of the second measuring unit from a first spectrum of the first signal and a second spectrum of the second signal; and
a subtraction unit that subtracts the second spectrum from the first spectrum so as to cancel the noise included in the first spectrum and the second spectrum, using the ratio estimated by the estimation unit.

13. A signal processing method comprising:
acquiring, by a first acquisition unit, a first signal indicating a pulse wave of a living body from a first measuring unit that measures the pulse wave;
acquiring, by a second acquisition unit, a second signal indicating the pulse wave of the living body from a second measuring unit that measures the pulse wave at different sensitivities from the first measuring unit;
estimating, by an estimation unit, a ratio of sensitivity of the first measuring unit to sensitivity of the second measuring unit from a first spectrum of the first signal and a second spectrum of the second signal; and
subtracting, by a subtraction unit, the second spectrum from the first spectrum so as to cancel noise included in the first spectrum and the second spectrum, using the ratio estimated by the estimation unit.
